(19) United States
(12) Patent Application Publication
(10) Pub. No.: US 2024/0088215 A1
(43) Pub. Date: Mar. 14, 2024

(54) TRENCH MOSFET DEVICE AND MANUFACTURING METHOD THEREFOR

(71) Applicant: Lingrui Semiconductor (Shanghai) Co., Ltd., Shanghai (CN)

(72) Inventors: Cesare Ronsisvalle, Shanghai (CN); Fanghua Li, Shanghai (CN); Shuntao Hu, Shanghai (CN); Guixin Liu, Shanghai (CN)

(21) Appl. No.: 18/513,576

(22) Filed: Nov. 19, 2023

(30) Foreign Application Priority Data
Jul. 18, 2023 (CN) 202310875766.3

(51) Int. Cl. H01L 29/06; H01L 21/04; H01L 29/16; H01L 29/40; H01L 29/66; H01L 29/78

(52) U.S. Cl. CPC H01L 29/063; H01L 21/047; H01L 29/1608; H01L 29/401; H01L 29/407; H01L 29/66068; H01L 29/7813

(57) ABSTRACT

The present invention discloses a trench MOSFET device manufacturing method, comprising: epitaxially forming a base area on a substrate; forming a first trench in the base area; forming a P-type layer on the inner surface of the first trench; filling the P-type layer with polysilicon; forming a second trench above the first trench; and forming a gate structure in the second trench. The present invention correspondingly discloses a trench MOSFET device. A smaller on-resistance is obtained by the concept of super junction, the Miller capacitance from a gate electrode to a drain electrode is reduced by the polysilicon technology of separated trenches, and a trench MOSFET device with a compact structure, a high primitive cell density and a high current density can be manufactured.

### TECHNICAL FIELD

The present invention relates to the technical field of semiconductors, and particularly relates a trench MOSFET device and a manufacturing method therefor.

### BACKGROUND

At present, with the development of semiconductor technology, power devices, as an important part of integrated circuits, are widely used in automobile electronics, communication equipment and other fields. In the prior art, unipolar power devices made of the third generation of semiconductor SiC material are mostly used as power semiconductor switching devices, and the concept of super junction and the polysilicon technology of separated trenches are mostly used to fabricate Si-based devices. At present, the main SiC power devices on the market are planar MOS and trench MOS, the concept of single trench or double trenches is mainly adopted by the trench MOS, and a gate trench and a source trench are horizontally divided into a left structure and a right structure when the concept of double trenches is adopted.

However, the concept of super junction and the polysilicon technology of separated trenches are not utilized at the same time to fabricate SiC devices in prior art, and the existing trench MOSFET devices are not compact enough in structure and have high on-resistance, which directly affects the performance of the MOSFET devices.

Therefore, how to combine the concept of super junction and the polysilicon technology of separated trenches to provide a manufacturing method for a MOSFET device with a compact structure and a low on-resistance is a problem to be urgently solved by those skilled in the art.

### SUMMARY

In view of this, the present invention provides a trench MOSFET device and a manufacturing method therefor, in which a smaller on-resistance is obtained by the concept of super junction, the Miller capacitance from a gate electrode to a drain electrode is reduced by the polysilicon technology of separated trenches, and a trench MOSFET device with a compact structure and a high primitive cell density per unit area can be produced.

To achieve the above purpose, the present invention adopts the following technical solution:

A trench MOSFET device manufacturing method, comprising:
Epitaxially forming a base area on a substrate;
Forming a first trench in the base area;
Forming a P-type layer on the inner surface of the first trench;
Filling the P-type layer with polysilicon;
Forming a second trench above the first trench;
Forming a gate structure in the second trench.

Preferably, the step of epitaxially forming a base area on a substrate specifically comprises:
Forming an epitaxial layer on the substrate by depositing;
Correspondingly forming a source film and a body layer film on the upper surface of the epitaxial layer, wherein the source film is located on the upper surface of the body layer film; constituting a source layer by the source film, and constituting a P-type body layer by the body layer film;
Constituting the base area by the epitaxial layer, the source layer and the P-type body layer together.

Preferably, the step of forming a P-type layer on the inner surface of the first trench specifically comprises:
Implanting aluminum ions or boron ions into the first trench at a preset angle to form a P-type layer on the bottom and side walls of the first trench.

Preferably, the step of forming a second trench above the first trench specifically comprises:
Forming a second trench above the first trench by photo-exposure and etching respectively through the source layer and the P-type body layer, wherein the second trench has a large width and a small depth compared with the first trench, and the polysilicon filled in the P-type layer is used as source polysilicon.

Preferably, the step of forming a gate structure in the second trench specifically comprises: forming a gate structure by a sacrificial oxidation process, a photolithography process, a gate oxidation process, a polysilicon filling process, a polysilicon photolithography process and an etching process, forming a gate oxide layer on the side walls and bottom of the second trench, and forming gate polysilicon in the gate oxide layer.

Preferably, the trench MOSFET device manufacturing method further comprises: forming an interlayer medium on the surface of the gate structure by depositing, forming a contact opening by etching, implanting ions to form a P+ layer, growing a metal on the upper surface of the interlayer medium as the source electrode, connecting the source electrode respectively with the source layer and the P-type body layer, wherein the P+ layer is located at the contact plane between the source electrode and the P-type body layer at the bottom of the contact opening, and forming a drain electrode after the lower surface of the substrate is ground and the backside metal is deposited.

A trench MOSFET device, comprising: the substrate, the base area, the first trench and the second trench;

The base area is located on the upper surface of the substrate, the second trench is located above the first trench, and both trenches are formed in the base area;

The P-type layer is formed on the inner surface of the first trench, and the P-type layer is filled with polysilicon.

Preferably, the base area comprises the source layer, the P-type body layer and the epitaxial layer distributed sequentially from top to bottom;

Preferably, the source polysilicon is arranged in the P-type layer;

The gate oxide layer is formed on the side walls and bottom of the second trench, and the gate polysilicon is formed in the gate oxide layer.

Preferably, trench MOSFET device further comprises: the source electrode, the P+ layer, the interlayer medium and the drain electrode;

The interlayer medium is located on the upper surface of the gate polysilicon, the P+ layer is located at the contact plane between the source electrode and the P-type body layer at the bottom of the contact opening, the source electrode is located on the upper surface of the interlayer medium, the source electrode is respectively connected with the source layer and the P-type body layer, and the drain electrode is located on the lower surface of the substrate.

It can be known from the above technical solution that compared with the prior art, the present invention provides a trench MOSFET device and a manufacturing method therefor, in which a super junction structure is formed by the P-type layer and the epitaxial layer to obtain an on-resistance smaller than that of a conventional trench structure, the Miller capacitance from a gate electrode to a drain electrode is reduced by the polysilicon technology of separated trenches, and a trench MOSFET device with a compact structure, a high primitive cell density per unit area and a high current density can be produced, which can significantly increase the power density of the device, reduce the cost and improve the reliability of the product.

### DESCRIPTION OF DRAWINGS

To more clearly describe the technical solutions in the embodiments of the present invention or in the prior art, the drawings required to be used in the description of the embodiments or the prior art will be simply presented below. Apparently, the drawings in the following description are merely the embodiments of the present invention, and for those ordinary skilled in the art, other drawings can also be obtained according to the provided drawings without contributing creative labor.

FIG. 1 is a flow chart of a trench MOSFET device manufacturing method provided by the present invention.

FIGS. 2-9 are cross-section diagrams of each stage of a trench MOSFET device manufacturing method provided by the present invention.

FIG. 10 is a cross-section diagram of a trench MOSFET device provided by the present invention.

Reference signs: 1—substrate, 2—epitaxial layer; 3—P-type body layer; 4—source layer; 5—first hard mask; 6—first trench; 7—P-type layer; 8—polysilicon; 9—second hard mask; 10—second trench; 11—gate polysilicon; 12—gate oxide layer; 13—source polysilicon; 14—interlayer medium; 15—P+ layer; 16—source electrode; 17—drain electrode.

### DETAILED DESCRIPTION

The technical solution in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

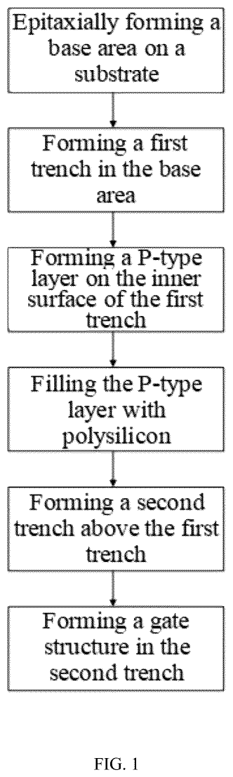

As shown in FIG. 1, the embodiment of the present invention discloses a trench MOSFET device manufacturing method, comprising:
Epitaxially forming a base area on a substrate;
Forming a first trench in the base area;
Forming a P-type layer on the inner surface of the first trench;
Filling the P-type layer with polysilicon;
Forming a second trench above the first trench;
Forming a gate structure in the second trench.

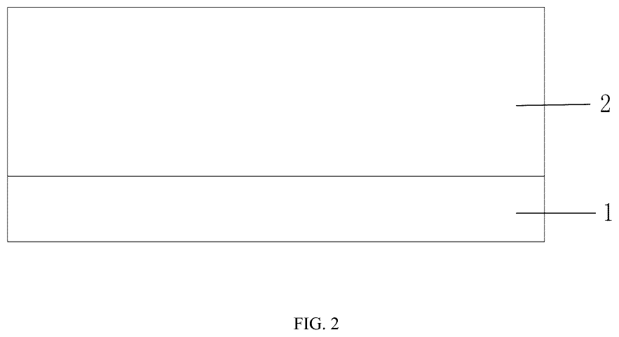

FIGS. 2-9 show each stage of the trench MOSFET device manufacturing method provided by the present invention.

As shown in FIG. 2, an epitaxial layer 2 is formed on the substrate 1 by depositing.

Preferably, the substrate 1 is made of SiC material, and nitrogen or phosphorus is doped during the formation of the SiC substrate to reduce the resistivity.

Preferably, the thickness and resistivity of the epitaxial layer 2 are set according to the target voltage of a device.

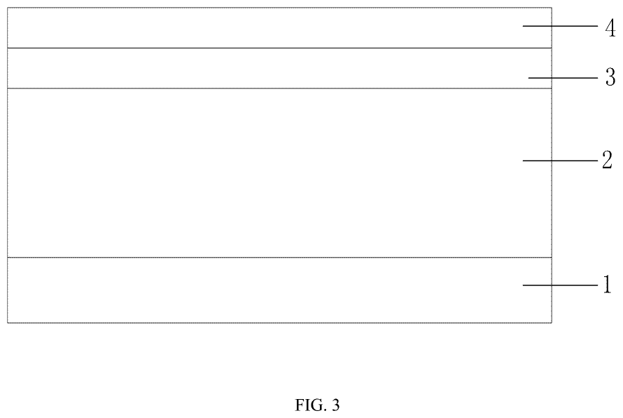

As shown in FIG. 3, photolithography and ion implantation or epitaxy are performed on the upper surface of the epitaxial layer 2 to correspondingly form a source film and a body layer film, wherein the source film is located on the upper surface of the body layer film; a source layer 4 is constituted by the source film, and a P-type body layer 3 is constituted by the body layer film; the base area is constituted by the epitaxial layer 2, the source layer 4 and the P-type body layer 3 together.

Preferably, the P-type body layer 3 is formed by implanting aluminum ions or boron ions, and is a SiC layer containing the second class of conductivity (P-type conduction); the source layer 4 is formed by implanting nitrogen ions or phosphorus ions, and is a SiC layer containing the first class of conductivity.

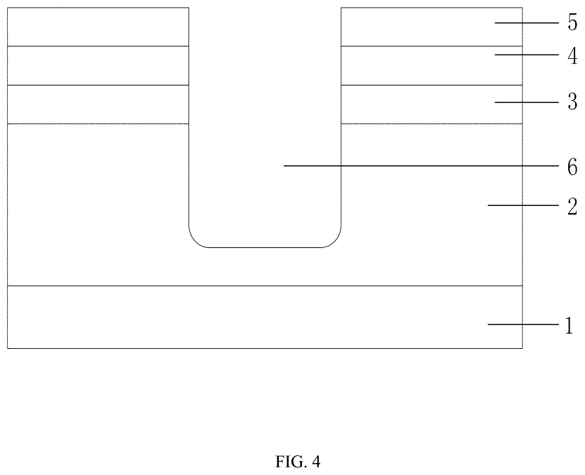

As shown in FIG. 4, a first hard mask 5 is formed on the upper surface of the base area, and a first trench 6 is formed in the base area.

Preferably, the first hard mask 5 is made of silicon dioxide.

Preferably, after the first hard mask 5 is formed, the base area is etched to form the first trench 6.

Preferably, the depth of the first trench 6 is set according to the target voltage of the device; the deeper the trench, the higher the voltage.

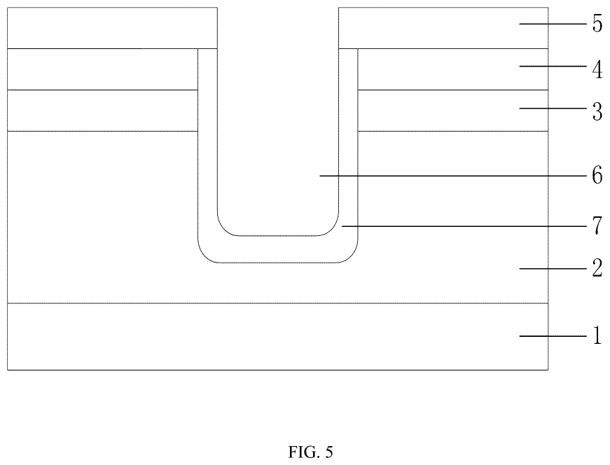

As shown in FIG. 5, aluminum ions or boron ions are implanted into the first trench at a preset angle to form a P-type layer 7 on the bottom and side walls of the first trench 6.

Preferably, the preset angle is set according to the width and the depth of the trench and the thickness of the layer to be implanted.

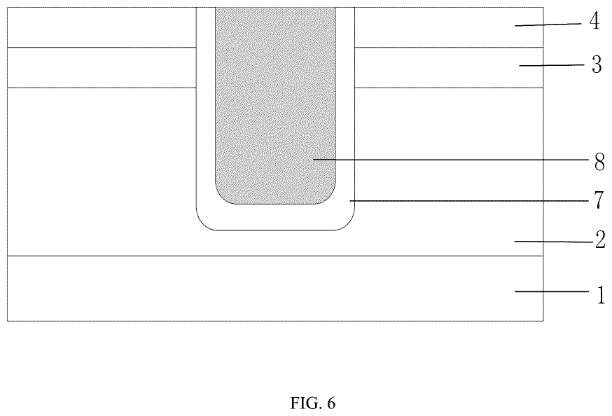

As shown in FIG. 6, the first hard mask 5 is removed, the P-type layer 7 is filled with polysilicon 8, excess polysilicon is removed by chemical and mechanical polishing, plasma etching or other etching methods to make the surface of the polysilicon 8 in the same horizontal plane with the source layer 4.

Preferably, the polysilicon 8 filled is doped with boron or other P-type doping element, thus the purpose of reducing the resistance is realized.

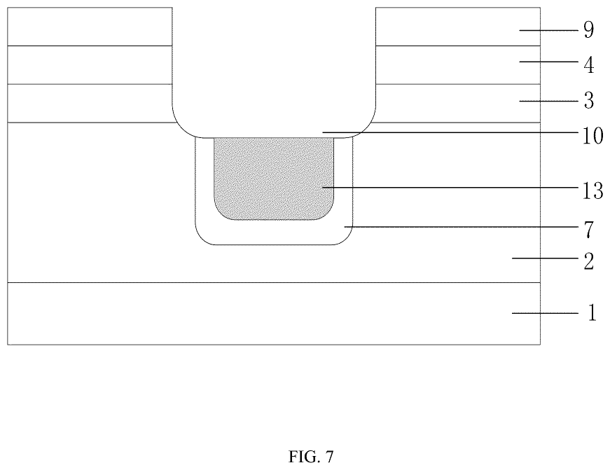

As shown in FIG. 7, a second hard mask 9 is formed on the upper surface of the base area by depositing, a second trench 10 is formed above the first trench 6 by photo-exposure and etching respectively through the second hard mask 9, the source layer 4 and the P-type body layer 3, wherein the second trench 10 has a large width and a small depth compared with the first trench 6, the polysilicon 8 filled in the trench enclosed by the P-type layer 7 is used as source polysilicon 13, and the source polysilicon 13 is separated from the epitaxial layer 2 by the P-type layer 7.

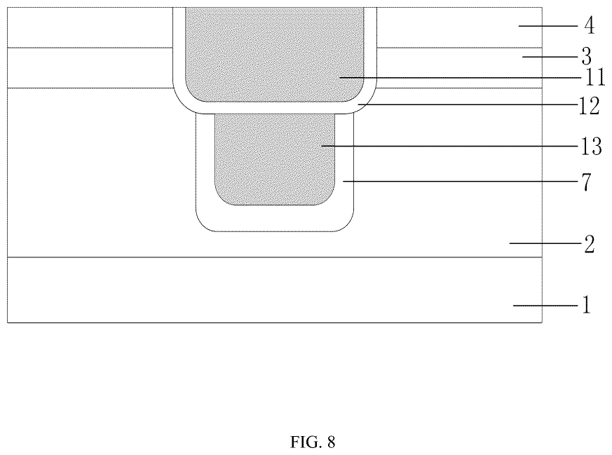

As shown in FIG. 8, a gate structure is formed in the second trench 10 by a sacrificial oxidation process, a photolithography process, a gate oxidation process, a polysilicon filling process, a polysilicon photolithography process and an etching process, and the second hard mask 9 is removed; a gate oxide layer 12 is formed on the side walls and bottom of the second trench 10, and the trench enclosed by the gate oxide layer 12 is filled with gate polysilicon 11.

Preferably, the gate polysilicon 11 is separated from the source polysilicon 13 by the gate oxide layer 12.

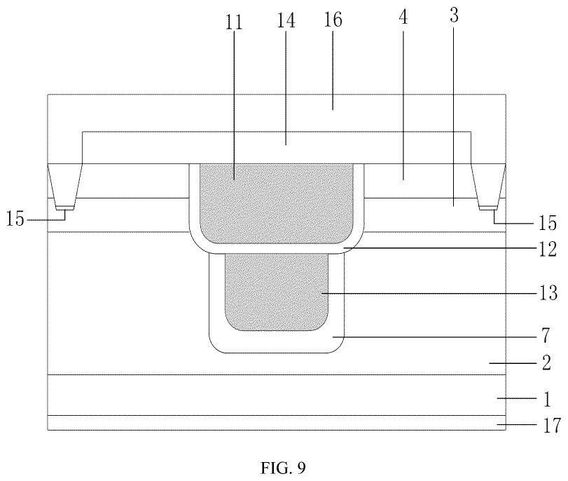

As shown in FIG. 9, an interlayer medium 14 is formed on the surface of the gate structure by depositing, a contact opening is formed by etching, ions are implanted to form a P+ layer 15, a metal is grown on the upper surface of the interlayer medium 14 as a source electrode 16, the source electrode 16 is connected respectively with the source layer 4 and the P-type body layer 3, wherein the P+ layer 15 is located at the contact plane between the source electrode 16 and the P-type body layer 3 at the bottom of the contact opening, and a drain electrode 17 is formed after the lower surface of the substrate 1 is ground and the backside metal is deposited.

Preferably, good ohmic contact is guaranteed by the P+ layer 15.

Preferably, after the gate structure is formed, a gate contact opening and a source contact opening are formed based on a standard power device manufacturing process; the source electrode 16 is connected with the source polysilicon 13, and a gate electrode is connected with the gate polysilicon 11.

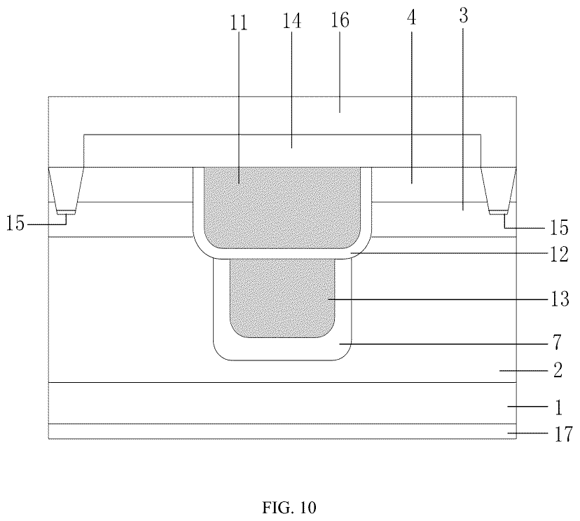

As shown in FIG. 10, the present invention discloses a trench MOSFET device, comprising: the substrate 1, the base area, the first trench and the second trench;

The base area is located on the upper surface of the substrate 1, the second trench is located above the first trench, and both trenches are formed in the base area;

The P-type layer 7 is formed on the inner surface of the first trench, and the P-type layer 7 is filled with the polysilicon 8.

Preferably, the base area comprises the source layer 4, the P-type body layer 3 and the epitaxial layer 2 distributed sequentially from top to bottom;

Preferably, the trench enclosed by the P-type layer 7 is filled with the source polysilicon 13, and the source polysilicon 13 is separated from the epitaxial layer 2 by the P-type layer 7;

A gate oxide layer 12 is formed on the side walls and bottom of the second trench, and the trench enclosed by the gate oxide layer 12 is filled with the gate polysilicon 11.

Preferably, trench MOSFET device further comprises: the source electrode 16, the P+ layer 15, the interlayer medium 14 and the drain electrode 17;

The interlayer medium 14 is located on the upper surface of the gate structure, the P+ layer 15 is located at the contact plane between the source electrode 16 and the P-type body layer 3 at the bottom of the contact opening, the source electrode 16 is located on the upper surface of the interlayer medium 14, the source electrode 16 is respectively connected with the source layer 4 and the P-type body layer 3, and the drain electrode 17 is located on the lower surface of the substrate 1.

Each embodiment in the description is described in a progressive way. The difference of each embodiment from each other is the focus of explanation. The same and similar parts among all of the embodiments can be referred to each other. For a device disclosed by the embodiments, because the device corresponds to a method disclosed by the embodiments, the device is simply described. Refer to the description of the method part for the related part.

The above description of the disclosed embodiments enables those skilled in the art to realize or use the present invention. Many modifications to these embodiments will be apparent to those skilled in the art. The general principle defined herein can be realized in other embodiments without departing from the spirit or scope of the present invention. Therefore, the present invention will not be limited to these embodiments shown herein, but will conform to the widest scope consistent with the principle and novel features disclosed herein.

What is claimed is:

1. A trench MOSFET device manufacturing method, comprising:
epitaxially forming a base area on a substrate;
the step of epitaxially forming a base area on a substrate specifically comprises:
forming an epitaxial layer on the substrate by depositing;
correspondingly forming a source film and a body layer film on the upper surface of the epitaxial layer, wherein the source film is located on the upper surface of the body layer film;
constituting a source layer by the source film, and constituting a P-type body layer by the body layer film;
constituting the base area by the epitaxial layer, the source layer and the P-type body layer together;
forming a first trench in the base area;
forming a P-type layer on the inner surface of the first trench;
filling the P-type layer with polysilicon; the polysilicon filled in the P-type layer is used as source polysilicon;
forming a second trench above the first trench;
forming a gate structure in the second trench;
the step of forming a gate structure in the second trench specifically comprises: forming a gate structure by a sacrificial oxidation process, a photolithography process, a gate oxidation process, a polysilicon filling process, a polysilicon photolithography process and an etching process, forming a gate oxide layer on the side walls and bottom of the second trench, and forming gate polysilicon in the gate oxide layer; separating the gate polysilicon from the source polysilicon by the gate oxide layer.

2. The trench MOSFET device manufacturing method according to claim 1, wherein the step of forming a P-type layer on the inner surface of the first trench specifically comprises:
implanting aluminum ions or boron ions into the first trench at a preset angle to form a P-type layer on the bottom and side walls of the first trench.

3. The trench MOSFET device manufacturing method according to claim 2, wherein the step of forming a second trench above the first trench specifically comprises:
forming a second trench above the first trench by photo-exposure and etching respectively through the source layer and the P-type body layer, wherein the second trench has a large width and a small depth compared with the first trench.

4. The trench MOSFET device manufacturing method according to claim 1, further comprising: forming an interlayer medium on the surface of the gate structure by depositing, forming a contact opening by etching, implanting ions to form a P+ layer, growing a metal on the upper surface of the interlayer medium as the source electrode, connecting the source electrode respectively with the source layer and the P-type body layer, wherein the P+ layer is located at the contact plane between the source electrode and the P-type body layer at the bottom of the contact opening, and forming a drain electrode after the lower surface of the substrate is ground and the backside metal is deposited.

5. A trench MOSFET device, comprising: the substrate, the base area, the first trench and the second trench;
the base area is located on the upper surface of the substrate, the second trench is located above the first trench, and both trenches are formed in the base area;
the P-type layer is formed on the inner surface of the first trench, and the P-type layer is filled with polysilicon.
the base area comprises the source layer, the P-type body layer and the epitaxial layer distributed sequentially from top to bottom;
the source polysilicon is arranged in the P-type layer;
the gate oxide layer is formed on the side walls and bottom of the second trench, and the gate polysilicon is formed in the gate oxide layer.

6. The trench MOSFET device according to claim 5, further comprising: the source electrode, the P+ layer, the interlayer medium and the drain electrode;
the interlayer medium is located on the upper surface of the gate polysilicon, the P+ layer is located at the contact plane between the source electrode and the P-type body layer at the bottom of the contact opening, the source electrode is located on the upper surface of the interlayer medium, the source electrode is respectively connected with the source layer and the P-type body layer, and the drain electrode is located on the lower surface of the substrate.
